(19) United States
(12) Patent Application Publication
(10) Pub. No.: US 2010/0050941 A1
(43) Pub. Date: Mar. 4, 2010

(54) ROLL-TO-ROLL TYPE THIN FILM PATTERN FORMING APPARATUS

(75) Inventors: Dong Joo Shin, Gunpo (KR); Jeong Min Cho, Seongnam (KR); Young Woo Lee, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/400,379

(22) Filed: Mar. 9, 2009

(30) Foreign Application Priority Data
Aug. 29, 2008 (KR) 10-2008-0085462

(51) Int. Cl. C23C 16/00; C23C 14/34

(52) U.S. Cl. 118/721; 204/298.11

(57) ABSTRACT

An apparatus for forming a thin film pattern according to an aspect of the invention may include: a vacuum chamber including a mask loading part and a film forming part having a window openable or closable with respect to the mask loading part; an unwinding roll and a winding roll disposed in the film forming part and running a sheet; a source containing unit accommodating a deposition source and mounted such that the deposition source is evaporated to deposit a thin film on the sheet located on the evaporation area; at least one mask having a pattern defining a pattern of the thin film to be deposited on the sheet, and arranged in the mask loading part; a mask moving unit moving the at least one mask arranged in the mask loading part toward a deposition position of the film forming part or moving the mask in a reverse direction; and a shutter unit selectively preventing a movement of the deposition source evaporated toward the mask from the source containing unit.

### CROSS-REFERENCE TO RELATED APPLICATIONS

This application claims the priority of Korean Patent Application No. 2008-0085462 filed on Aug. 29, 2008, in the Korean Intellectual Property Office, the disclosure of which is incorporated herein by reference.

### BACKGROUND OF THE INVENTION

1. Field of the Invention

The present invention relates to roll-to-roll type thin film forming apparatuses, and more particularly, to a roll-to-roll type thin film pattern forming apparatus that forms a desired thin film pattern on a sheet running between rolls.

2. Description of the Related Art

As digital electronic products have been reduced in size and have increased in functionality, various types of passive components have correspondingly been reduced in size, thickness, and weight while the functions of these passive components have been upgraded. Especially, a large number of capacitors are used in small portable electronic products, such as camera phones, DMB phones, and navigation devices. In addition to ultrathin films and multilayers, there is a growing need to increase the capacity and functionality of capacitors.

However, an existing screen printing method is limited when achieving high-capacity capacitors within the same chip size. In order to overcome this limitation, various kinds of methods have been attempted, and among them, there is a roll-to-roll process. Considerable consideration has been given to the roll-to-roll process since it is more suitable for mass production than an existing batch type process in realizing a display or a device on a flexible substrate.

The roll-to-roll type apparatus for forming a thin film has advantages in terms of mass production because the process is performed while a sheet is continuously transferred, but it is difficult to form a pattern used to manufacture a device. Also, there is another method of forming a layer on a sheet wound in a roll, cutting the sheet having the layer thereon, and arranging the cut sheet. However, since this method may not allow mass production, it is difficult to use the method when repeating the formation of a thin film pattern. Therefore, there is a need for a technique that forms a thin film pattern while the sheet is located between one roll and another.

However, when a thin film pattern is formed using a roll-to-roll process, the thin film pattern becomes defective due to the use of a mask. For example, in a process of forming a roll-to-roll thin film to manufacture a multilayer ceramic capacitor (MLCC), when an internal electrode, such as a thin film formed of Ni, is formed using a roll mask having an electrode pattern formed thereon within a vacuum chamber, it is difficult to prevent blurring of the electrode pattern since the rolls continue to be driven even when a film is formed to form an electrode, which causes a reduction of reliability and degradation in the electrical characteristics of a chip.

### SUMMARY OF THE INVENTION

An aspect of the present invention provides an apparatus for forming a thin film pattern that allows the replacement of a mask instead of using a mask moved by rolls to prevent the blurring of an electrode pattern and dust generation when a thin film pattern is formed.

According to an aspect of the present invention, there is provided an apparatus for forming a thin film pattern, the apparatus including: a vacuum chamber including a mask loading part and a film forming part having a window openable or closable with respect to the mask loading part; an unwinding roll and a winding roll disposed in the film forming part and running a sheet; a source containing unit accommodating a deposition source and mounted such that the deposition source is evaporated to deposit a thin film on the sheet located on the evaporation area; at least one mask having a pattern defining a pattern of the thin film to be deposited on the sheet, and arranged in the mask loading part; a mask moving unit moving the at least one mask arranged in the mask loading part toward a deposition position of the film forming part or moving the mask in a reverse direction; and a shutter unit selectively preventing a movement of the deposition source evaporated toward the mask from the source containing unit.

The at least one mask arranged in the mask loading part may include a plurality of masks, and the mask moving unit may select one of the plurality of masks, and move the selected mask to the deposition position of the film forming part from the mask loading part or moves the selected mask in a reverse direction.

The apparatus may further include a support plate located at a deposition area between the unwinding roll and the winding roll to support the sheet.

The mask moving unit may include a mask loader located in the mask loading part a mask lifter located in the film forming part, and the mask loader may transfer the mask from the mask loading part to the mask lifter, and the mask lifter may move the mask in a vertical direction such that the mask makes tight contact with the sheet located on the support plate.

The sheet may be a dielectric green sheet, and the deposition source may be an electrode material including Ag or Ni.

The sheet may be a flexible substrate.

The thin film may be deposited using one selected from the group consisting of e-beam deposition, thermal deposition, sputtering, ion-beam deposition, and pulse laser deposition.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating an apparatus for forming a thin film according to an exemplary embodiment of the present invention;

FIG. 2 is a schematic view illustrating an apparatus for forming a thin film (mask loading process) according to an exemplary embodiment of the present invention;

FIG. 3 is a schematic view illustrating an apparatus for forming a thin film (film forming process) according to an exemplary embodiment of the present invention; and

FIG. 4 is a schematic view illustrating an apparatus for forming a thin film (sheet moving process) according to an exemplary embodiment of the present invention.

### DETAILED DESCRIPTION OF THE PREFERRED EMBODIMENT

Exemplary embodiments of the present invention will now be described in detail with reference to the accompanying drawings.

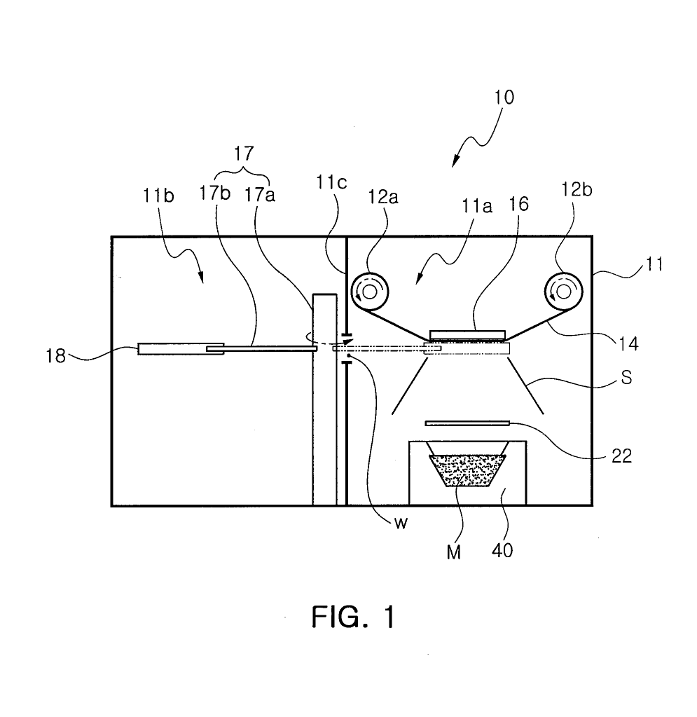

FIG. 1 is a schematic view illustrating an apparatus for forming a thin film according to an exemplary embodiment of the invention.

Referring to FIG. 1, a thin film pattern forming apparatus 10 according to this embodiment includes a vacuum chamber 11. The vacuum chamber 11 includes a mask loading part 11b, a film forming part 11a, and a separation wall 11c located therebetween and having a window w. The window w of the separation wall 11c can be opened or closed between the mask loading part 11b and the film forming part 11a.

A sheet 14 where a thin film pattern will be formed runs across a deposition area by an unwinding roll 12a and a winding roll 12b. A source containing unit 20 that accommodates a deposition source M is formed under the deposition area. The deposition source M may be a metal source, such as Ag and Ni, which is used to form an electrode pattern. Though not shown in FIG. 1, the thin film pattern forming apparatus 10 includes a unit evaporating the deposition source M, for example, an electronic beam, to form a thin film on the surface of the sheet 14.

The thin film pattern forming apparatus 10 according to this embodiment further includes a shielding film S to prevent thin-film deposition on another sheet area other than a desired deposition area. After the sheet 14 is completely run to a desired position, a shutter 22 is opened to start the thin-film deposition. The thin film may be deposited using one selected from the group consisting of e-beam deposition, thermal deposition, sputtering, ion-beam deposition, and pulse laser deposition.

In this embodiment, a mask 18 having a pattern that defines a thin film pattern is disposed in the mask loading part 11b. As described above, as the mask loading part 11b is a part of the vacuum chamber 11, the mask loading part 11b has a condition such as vacuum or low pressure, which is similar to that of the film forming part 11a. The mask 18, located in the mask loading part 11b, may be disposed at a desired position of the film forming part 11a by a mask moving unit 17.

The mask moving unit 17, shown in FIG. 1, is provided as a mask loader that is disposed in the mask loading part 11b. The mask moving unit 17 includes an arm unit 17b onto which the mask 18 is mounted and a rotary column 17a to which the arm unit 17b is fixed.

In this embodiment, the rotary column 17a rotates such that the arm unit 17b having the mask 18 mounted thereon faces the window w of the separation wall 11c, and then the arm unit 17b is extended to move the mask 18 to the desired deposition area.

Like this embodiment, the mask loading part 11b is separately provided, and the mask 18 is moved to the deposition area or moved in a reverse direction by the mask moving unit 17, so that the mask 18, which is used several times during the roll-to-roll thin film forming process, can be easily replaced, recycled, and repaired without releasing the vacuum state of the film forming part 11a.

That is, the mask 18 is moved into the mask loading part 11b, and then the window w of the separation wall 11c is closed, so that a process can be performed on the mask 18, located in the mask loading part 11b, without releasing the vacuum state of the film forming part 11a.

The thin film pattern forming apparatus according to this embodiment can be advantageously used in an MLCC manufacturing process or a process of manufacturing a flexible device. In the MLCC manufacturing process, the sheet may be a dielectric green sheet, and the deposition source may be an electrode material, formed of Ag or Ni.

Similarly, the sheet may be used in a process of manufacturing a flexible device using a flexible substrate.

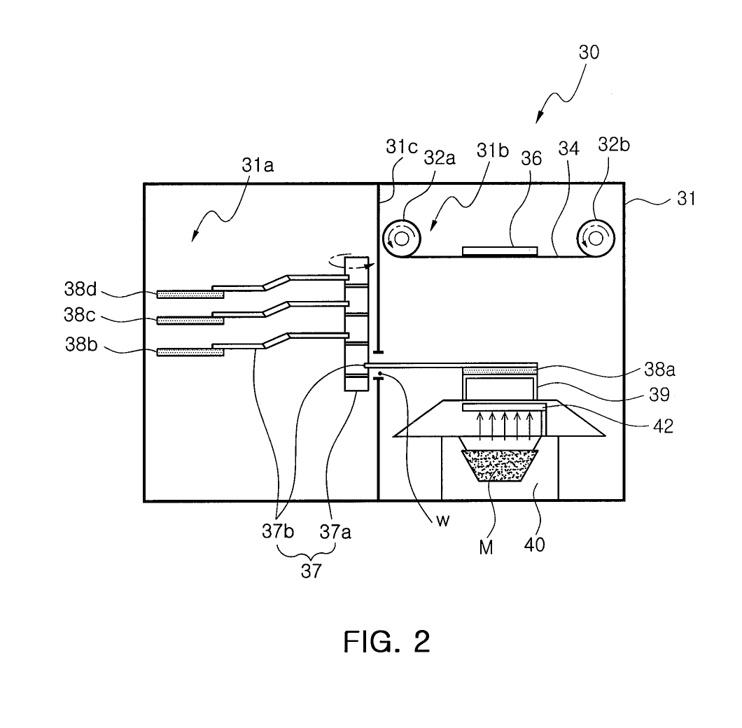

A plurality of masks may be disposed in the mask loading part. The plurality of masks may be selected and moved to a desired position of a film forming part or moved in a reverse direction. This embodiment is illustrated in FIGS. 2 through 4.

FIGS. 2 through 4 are schematic views illustrating the operation of individual components of a thin film pattern forming apparatus in a mask loading process, a film forming process, and a sheet moving process, respectively.

First, referring to FIG. 2, a thin film pattern forming apparatus 30 according to this embodiment includes a vacuum chamber 31. The vacuum chamber 31 has a mask loading part 31a, a film forming part 31b, and a separation wall 31c located therebetween and having a window w. The window w of the separation wall 31c can be opened or closed between the mask loading part 31a and the film forming part 31b.

A sheet 34 where a thin film pattern will be formed runs across a deposition area by an unwinding roll 32a and a winding roll 32b. A support plate 36 is additionally mounted to the deposition area to support the sheet 34. A source containing unit 40 that accommodates a deposition source M is located under the deposition area. After the sheet 34 is completely run to a desired position, a shutter 42 is opened to start thin-film deposition.

In this embodiment, four masks 38a to 38d having patterns formed thereon to define a thin film pattern may be disposed in the mask loading part 31b. The mask moving unit includes a mask loader 37, disposed in the mask loading part 31a, and a mask lifter 39. The mask loader 37 selects one from the masks 38a to 38d to transfer the selected mask to the mask lifter 39 from the mask loading part 31a. The mask loader 37 includes an arm unit 37b onto which the mask is mounted and a rotary column 37a to which the arm unit 37b is fixed.

As shown in FIG. 2, one mask 38a can be transferred to a desired position of the film forming part 31b from the mask loading part 31a by the mask loader 37.

That is, the rotary column 37a rotates such that the arm unit 37b having the mask 38a mounted thereon faces the window w of the separation wall 31c, and then the arm unit 37b is extended to move the mask 38a to the desired deposition area. Therefore, the mask 38a can be moved to the desired position.

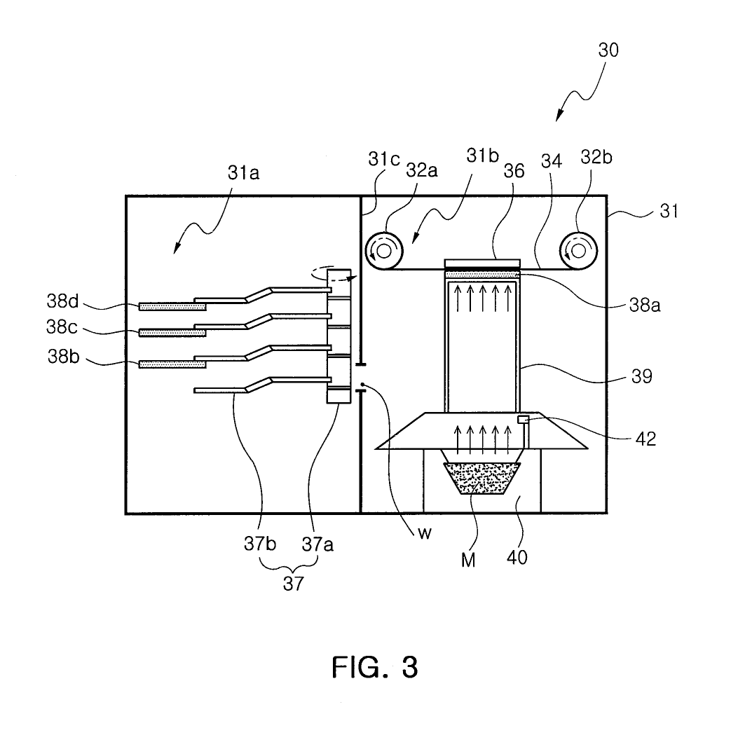

As shown in FIG. 3, the mask lifter 39 moves the transferred mask 38a along a vertical direction such that the transferred mask 38a makes tight contact with the sheet 34 located on the support plate 36.

As such, when the mask 38a is lifted to the sheet 34 by the mask lifter 39, the shutter 42 is opened to perform a thin-film pattern forming process. The mask 38a is transferred so that the mask 38 makes tight contact with the sheet 34 located on the support plate 36, thereby ensuring that a thin film pattern can be more accurately formed.

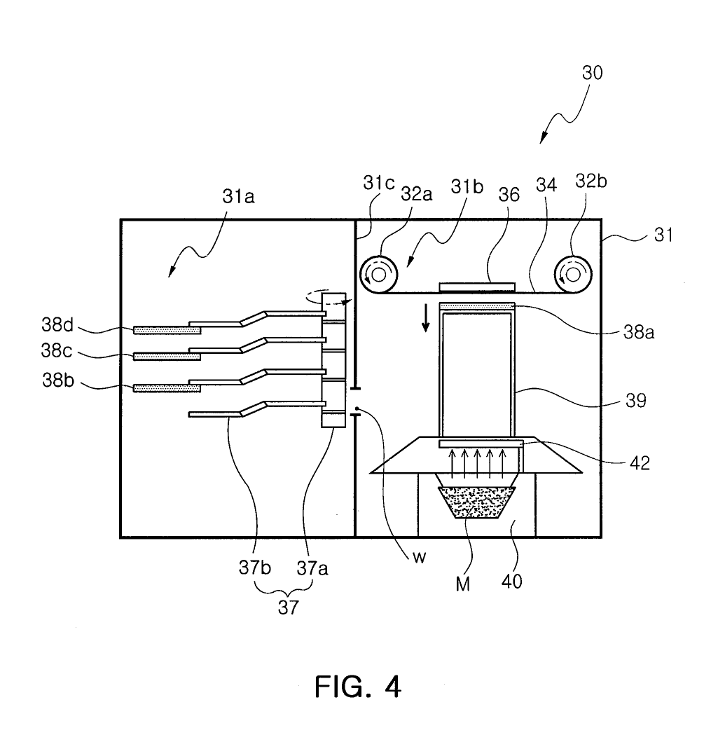

After the process of forming one film pattern is completed, the mask 38a is slightly lowered using the mask lifter 39, as shown in FIG. 4, to form a next thin film pattern. In this case, the shutter 42 is closed such that the evaporated source cannot move toward the sheet 34.

As such, while the sheet 34 is separated from the mask 38a, the sheet 34 is transferred such that another area of the sheet 34, where another pattern will be formed, is located on the support plate 36. After the sheet 34 is completely transferred, the mask 38a makes tight contact with the sheet 34 as shown in FIG. 2, and a process of forming a thin film pattern is performed. Then, as shown in FIG. 4, the process of transferring the sheet 34 is repeated to perform a continuous process of forming a thin film pattern. The thin film may be deposited using one selected from the group consisting of e-beam deposition, thermal deposition, sputtering, ion-beam deposition, and pulse laser deposition.

As described above, if the process of forming a pattern is repeated tens of times, excessive dust may occur on the surface of the mask to cause serious difficulties when forming an accurate pattern. In the vacuum chamber where a film is formed, a mask can be exchanged for another mask by a separate mask loading part and a separate mask moving unit. Like this embodiment, as five masks are arranged in a mask loading part to continuously perform a process of forming a thin film pattern, the number of thin film patterns manufactured can increase almost fivefold, thereby ensuring desired mass production.

As set forth above, according to exemplary embodiments of the invention, an apparatus for forming a thin film pattern has advantages of roll-to-roll type thin film equipment, and can prevent blurring of a pattern since a mask is not run by driving rolls while forming a thin film pattern, and reduce dust because of small movements of the mask. As the mask can be replaced in a cassette storing masks, the failure rate due to errors when forming a pattern is reduced, and in the long term, higher product reliability and yield can be expected.

While the present invention has been shown and described in connection with the exemplary embodiments, it will be apparent to those skilled in the art that modifications and variations can be made without departing from the spirit and scope of the invention as defined by the appended claims.

What is claimed is:

1. An apparatus for forming a thin film pattern, the apparatus comprising:
a vacuum chamber including a mask loading part and a film forming part having a window openable or closable with respect to the mask loading part;
an unwinding roll and a winding roll disposed in the film forming part and running a sheet;
a source containing unit accommodating a deposition source and mounted such that the deposition source is evaporated to deposit a thin film on the sheet located on a deposition area;
at least one mask having a pattern defining a pattern of the thin film to be deposited on the sheet, and arranged in the mask loading part;
a mask moving unit moving the at least one mask arranged in the mask loading part toward a deposition position of the film forming part or moving the mask in a reverse direction; and
a shutter unit selectively preventing a movement of the deposition source evaporated toward the mask from the source containing unit.

2. The apparatus of claim 1, wherein the at least one mask arranged in the mask loading part comprises a plurality of masks, and
the mask moving unit selects one of the plurality of masks, and moves the selected mask to the deposition position of the film forming part from the mask loading part or moves the selected mask in a reverse direction.

3. The apparatus of claim 1, further comprising a support plate located at the deposition area between the unwinding roll and the winding roll to support the sheet.

4. The apparatus of claim 3, wherein the mask moving unit comprises a mask loader located in the mask loading part a mask lifter located in the film forming part, and
the mask loader transfers the mask from the mask loading part to the mask lifter, and the mask lifter moves the mask in a vertical direction such that the mask makes tight contact with the sheet located on the support plate.

5. The apparatus of claim 1, wherein the sheet is a dielectric green sheet, and the deposition source is an electrode material including Ag or Ni.

6. The apparatus of claim 1, wherein the sheet is a flexible substrate.

7. The apparatus of claim 1, wherein the thin film is deposited using one selected from the group consisting of e-beam deposition, thermal deposition, sputtering, ion-beam deposition, and pulse laser deposition.
